(19) United States
(12) Patent Application Publication
(10) Pub. No.: US 2026/0114284 A1
(43) Pub. Date: Apr. 23, 2026

(54) WAFER-SCALE SYSTEM IN PACKAGE STRUCTURE AND METHOD FOR FORMING THE SAME

(71) Applicant: JCET Microelectronics (Jiangyin) Co., LTD., Jiangyin (CN)

(72) Inventors: Danfeng YANG, Jiangyin (CN); Songhua XU, Jiangyin (CN); Li XU, Jiangyin (CN); Haijie CHEN, Jiangyin (CN); Yaojian LIN, Jiangyin (CN)

(73) Assignee: JCET Microelectronics (Jiangyin) Co., LTD., Jiangyin (CN)

(21) Appl. No.: 19/343,966

(22) Filed: Sep. 29, 2025

(30) Foreign Application Priority Data
Oct. 23, 2024 (CN) 202411485168.6

(51) Int. Cl. H01L 23/00; H01L 21/54; H01L 21/56; H01L 23/24; H01L 23/31; H01L 23/367; H01L 25/065

(52) U.S. Cl. CPC H10W 42/121; H10W 74/01; H10W 74/124; H10W 76/05; H10W 76/47; H10W 90/00; H10W 40/22; H10W 74/15; H10W 90/724; H10W 90/733; H10W 90/734

(57) ABSTRACT

A wafer-scale system in package structure includes: a silicon substrate; a plurality of functional sub-modules arranged in an array mounted on the upper surface of the silicon substrate; a warping and stress adjustment structure mounted on the upper surface of the silicon substrate at the edges of the functional sub-modules; a stress cushioning flexible member structure mounted on the upper surface of the silicon substrate at the corner heads of the functional sub-modules; edge dummy devices of different sizes mounted on the upper surface of the edge area of the silicon substrate outside the array of the functional sub-modules; and a molding layer located on the upper surface of the silicon substrate, covering the functional sub-modules, the warping and stress adjustment structure, the stress cushioning flexible member structure and edge dummy devices.

### CROSS-REFERENCE TO RELATED APPLICATIONS

This application claims the benefit of priority to Chinese Application No. 202411485168.6, filed Oct. 23, 2024, which is incorporated herein by reference in its entirety.

### TECHNICAL FIELD

The present disclosure relates to the field of semiconductor package, and particularly relates to a wafer-scale system in package structure and a method for forming the same.

### BACKGROUND

System in Package (SiP) is the integration of multiple chips with different functions, such as opto-electronics, digital/logic, radio frequency, storage, etc., into a single package in the form of a chip stack or a package stack, thereby realizing a system that can realize the above multiple functions.

The demand of today's emerging fields (mobile devices, artificial intelligence, automotive electronics, data storage, and etc.) for data computing is growing exponentially, in order to meet the requirements of high density, high speed, high heat dissipation, low power consumption, low latency and etc. on high-performance computing, and the existing system in package is extended towards the wafer-scale, i.e., multiple semiconductor chips with multiple different functions are integrated on one silicon wafer to form a wafer-scale system in package structure.

### SUMMARY

The present disclosure firstly provides a wafer-scale system in package structure, including: a silicon substrate, the silicon substrate including opposed upper surface and lower surface; a plurality of functional sub-modules arranged in an array mounted on the upper surface of the silicon substrate, the plurality of functional sub-modules being electrically connected with the silicon substrate, and each of the functional sub-modules including four corner heads and edges located between adjacent corner heads; a warping and stress adjustment structure mounted on the upper surface of the silicon substrate at the edges of the functional sub-modules; a stress cushioning flexible member structure mounted on the upper surface of the silicon substrate at the corner heads of the functional sub-module; edge dummy devices of different sizes mounted on the upper surface of the edge area of the silicon substrate outside the array of the functional sub-modules; and a molding layer located on the upper surface of the silicon substrate, the molding layer covering the functional sub-modules, the warping and stress adjustment structure, the stress cushioning flexible member structure and edge dummy devices, the molding layer exposing the upper surface of the functional sub-modules, the warping and stress adjustment structure, the stress cushioning flexible member structure and edge dummy devices.

In an optional embodiment, the warping and stress adjustment structure includes a flexible layer and a rigid layer located on the upper surface of the flexible layer, and the rigidity of the flexible layer is smaller than the rigidity of the rigid layer.

In an optional embodiment, the material of the rigid layer of the warping and stress adjustment structure is silicon, silicon germanium, or silicon carbide, and the material of the flexible layer is at least one of a filler and a fiber-filled polymer composite material.

In an optional embodiment, the warping and stress adjustment structure is mounted on the upper surface of the silicon substrate, including: the warping and stress adjustment structure being directly contact-mounted on the upper surface of the silicon substrate, or the warping and stress adjustment structure being floatingly mounted on the upper surface of the silicon substrate.

In an optional embodiment, the warping and stress adjustment structure is one or more of a flip chip, a surface mount device, a functional device, a structural dummy piece, or a heat dissipation dummy piece.

In an optional embodiment, the number of warping and stress adjustment structures mounted on the upper surface of the silicon substrate at each edge of the functional sub-module is at least two, and the plurality of the warping and stress adjustment structures are arranged along a direction parallel to the edge of the functional sub-module.

In an optional embodiment, the silicon substrate includes an intermediate area and an edge area surrounding the intermediate area, a plurality of functional sub-modules are mounted on the upper surface of the intermediate area of the silicon substrate; and a plurality of dummy devices are mounted on the upper surface of the edge area of the silicon substrate.

In an optional embodiment, the edge dummy devices are one or more of a passive device, a heat dissipation discrete member, or a dummy piece.

In an optional embodiment, the dimension of the edge dummy devices far away from the intermediate area is smaller than the dimension of the edge dummy devices close to the intermediate area.

In an optional embodiment, the silicon substrate in the edge area further has a trench, which runs through or does not run through the silicon substrate, and the molding layer further fully fills the trench.

In an optional embodiment, it further includes: a heat dissipation cover mounted on the upper surface of the molding layer, the functional sub-module, the warping and stress adjustment structure, and the stress cushioning flexible member structure, as well as on the outer side of the molding layer and the silicon substrate, the heat dissipation cover including a horizontal cover top and a cover rim protruding from the lower surface of the edge of the horizontal cover top, and the lower surface of the horizontal cover top is horizontal or has an optional downward protrusion in the corresponding area of the functional sub-module, the warping and stress adjustment structure, and the stress cushioning flexible member structure, and the lower surface of the horizontal cover top of the heat dissipation cover is mounted on the upper surface of the molding layer, the functional sub-module, the warping and stress adjustment structure, and the stress cushioning flexible member structure, and the surface of the inner wall of the cover rim of the heat dissipation cover is mounted on the outer side surface of the molding layer and of the silicone substrate.

In an optional embodiment, the stress cushioning flexible member structure is a flexible structure, and the rigidity of the stress cushioning flexible member structure is smaller than the rigidity of the molding layer.

In an optional embodiment, the stress cushioning flexible member structure includes a first cushioning layer, a core layer located on the upper surface of the first cushioning layer, and a second cushioning layer located on the upper surface of the core layer, the second cushioning layer and the core layer having in them blind holes running through the second cushioning layer and the core layer, the molding layer exposing the blind holes.

In an optional embodiment, the lower surface of the horizontal cover top of the heat dissipation cover has a plurality of downward protruding anchoring protrusions, the anchoring protrusions being mounted in corresponding blind holes by means of bonding adhesive.

In an optional embodiment, the stress cushioning flexible member structure includes a first cushioning layer, a core layer located on the upper surface of the first cushioning layer, and a second cushioning layer located on the upper surface of the core layer, the core layer having in it blind holes, and a portion of the lower surface of the horizontal cover top of the heat dissipation cover being mounted on the upper surface of the second cushioning layer by means of bonding adhesive.

In an optional embodiment, the blind holes have cavities or the blind holes are fully filled with filler material.

In an optional embodiment, the surface of the sidewall of the blind holes further has a metal layer.

In an optional embodiment, it further includes: a reinforcement frame mounted on the lower surface of the silicon substrate, and the upper surface of an edge area of the reinforcement frame is mounted together with the lower surface of a bottom end of the cover rim of the heat dissipation cover on an outer side of the silicon substrate.

In an optional embodiment, the silicon substrate includes a silicon wafer body, a first redistribution layer located on the upper surface of the silicon wafer body and a second redistribution layer located on the lower surface of the silicon wafer body, and the reinforcement frame has in it a plurality of carving holes, and the carving holes expose a portion of the second redistribution layer.

In an optional embodiment, the upper surface of the edge area of the reinforcement frame has a protrusion structure, the lower surface of the bottom end of the cover rim of the heat dissipation cover of the outer side of the silicon substrate has a groove structure, and when the upper surface of the edge area of the reinforcement frame is mounted together with the lower surface of the bottom end of the cover rim of the heat dissipation cover of the outer side of the silicon substrate, the protrusion structure of the upper surface of the edge area of the reinforcement frame is mounted in a corresponding groove structure on the lower surface of the bottom end of the cover rim of the heat dissipation cover of the outer side of the silicon substrate by means of a bonding adhesive.

In an optional embodiment, the upper surface of the edge area of the reinforcement frame has a groove structure, and the lower surface of the bottom end of the cover rim of the heat dissipation cover of the outer side of the silicon substrate has a protrusion structure, and when the upper surface of the edge area of the reinforcement frame is mounted together with the lower surface of the bottom end of the cover rim of the heat dissipation cover of the outer side of the silicon substrate, the protrusion structure on the lower surface of the bottom end of the cover rim of the heat dissipation cover of the outer side of the silicon substrate is mounted in a corresponding groove structure of the upper surface of the edge area of the reinforcement frame by means of a bonding adhesive.

In an optional embodiment, the structure of each functional sub-module is the same, the functional sub-modules including at least two semiconductor chips, the at least two semiconductor chips being mounted on the upper surface of the silicon substrate in a flip-flop manner; each functional sub-module further includes an underfill layer filled between the lower surface of the semiconductor chip in each functional sub-module and the upper surface of the silicon substrate and covering the sides of the semiconductor chip.

In an optional embodiment, the diagonal dimension of the silicon substrate is 300 or 450±10 mm, or the diameter of the silicon substrate is 300 mm or 450±5 mm.

The present disclosure also provides a method for forming a wafer-scale system in package structure, including: providing a silicon substrate, the silicon substrate including opposed upper surface and lower surface; mounting a plurality of functional sub-modules arranged in an array on the upper surface of the silicon substrate, the plurality of functional sub-modules being electrically connected with the silicon substrate, and each of the functional sub-modules including four corner heads and edges located between adjacent corner heads; mounting a warping and stress adjustment structure on the upper surface of the silicon substrate at the edges of the functional sub-modules; mounting a stress cushioning flexible member structure on the upper surface of the silicon substrate at the corner heads of the functional sub-module; mounting edge dummy devices of different sizes on the upper surface of the edge area of the silicon substrate outside the array of the functional sub-modules; and forming a molding layer on the upper surface of the silicon substrate, the molding layer covering the functional sub-modules, the warping and stress adjustment structure, the stress cushioning flexible member structure and edge dummy devices, the molding layer exposing the upper surface of the functional sub-modules, the warping and stress adjustment structure, the stress cushioning flexible member structure and edge dummy devices.

In an optional embodiment, the warping and stress adjustment structure includes a flexible layer and a rigid layer located on the upper surface of the flexible layer, and the rigidity of the flexible layer is smaller than the rigidity of the rigid layer.

In an optional embodiment, mounting the warping and stress adjustment structure on the upper surface of the silicon substrate includes: directly contact-mounting the warping and stress adjustment structure on the upper surface of the silicon substrate, or floatingly mounting the warping and stress adjustment structure on the upper surface of the silicon substrate.

In an optional embodiment, the warping and stress adjustment structure is one or more of a flip chip, a surface mount device, a functional device, a structural dummy piece, or a heat dissipation dummy piece.

In an optional embodiment, the silicon substrate includes an intermediate area and an edge area surrounding the intermediate area, a plurality of functional sub-modules are mounted on the upper surface of the intermediate area of the silicon substrate; and a plurality of dummy devices are mounted on the upper surface of the edge area of the silicon substrate.

In an optional embodiment, it further includes: forming, in the silicon substrate in the edge area, a trench running through or not running through the silicon substrate; and when forming the molding layer, and the molding layer further fully fills the trench.

In an optional embodiment, it further includes: mounting a heat dissipation cover on the upper surface of the molding layer, the functional sub-module, the warping and stress adjustment structure, and the stress cushioning flexible member structure, as well as on the outer side of the molding layer and the silicon substrate, the heat dissipation cover including a horizontal cover top and a cover rim protruding from the lower surface of the edge of the horizontal cover top, and the lower surface of the horizontal cover top is horizontal or has an optional downward protrusion in the corresponding area of the functional sub-module, the warping and stress adjustment structure, and the stress cushioning flexible member structure, and the lower surface of the horizontal cover top of the heat dissipation cover is mounted on the upper surface of the molding layer, the functional sub-module, the warping and stress adjustment structure, and the stress cushioning flexible member structure, and the surface of the inner wall of the cover rim of the heat dissipation cover is mounted on the outer side surface of the molding layer and of the silicone substrate.

In an optional embodiment, the stress cushioning flexible member structure includes a first cushioning layer, a core layer located on the upper surface of the first cushioning layer, and a second cushioning layer located on the upper surface of the core layer, the second cushioning layer and the core layer having in them blind holes running through the second cushioning layer and the core layer, the molding layer exposing the blind holes.

In an optional embodiment, the lower surface of the horizontal cover top of the heat dissipation cover has a plurality of protruding anchoring protrusions, and when the mounting of the heat dissipation cover is carried out, the anchoring protrusions are mounted in corresponding blind holes by means of a bonding adhesive.

In an optional embodiment, the stress cushioning flexible member structure includes a first cushioning layer, a core layer located on the upper surface of the first cushioning layer, and a second cushioning layer located on the upper surface of the core layer, the core layer having in it blind holes, and when the mounting of the heat dissipation cover is carried out, a portion of the lower surface of the horizontal cover top of the heat dissipation cover is mounted on the upper surface of the second cushioning layer by means of bonding adhesive.

In an optional embodiment, it further includes: mounting a reinforcement frame on a lower surface of the silicon substrate, and the upper surface of an edge area of the reinforcement frame is mounted together with the lower surface of a bottom end of the cover rim of the heat dissipation cover on an outer side of the silicon substrate.

In an optional embodiment, the silicon substrate includes a silicon wafer body, a first redistribution layer located on the upper surface of the silicon wafer body and a second redistribution layer located on the lower surface of the silicon wafer body, and the reinforcement frame has in it a plurality of carving holes, and when the reinforcement frame is mounted, the carving holes expose a portion of the second redistribution layer.

In an optional embodiment, the upper surface of the edge area of the reinforcement frame has a protrusion structure, the lower surface of the bottom end of the cover rim of the heat dissipation cover of the outer side of the silicon substrate has a groove structure, and when the upper surface of the edge area of the reinforcement frame is mounted together with the lower surface of the bottom end of the cover rim of the heat dissipation cover of the outer side of the silicon substrate, the protrusion structure of the upper surface of the edge area of the reinforcement frame is mounted in a corresponding groove structure on the lower surface of the bottom end of the cover rim of the heat dissipation cover of the outer side of the silicon substrate by means of a bonding adhesive.

In an optional embodiment, the upper surface of the edge area of the reinforcement frame has a groove structure, and the lower surface of the bottom end of the cover rim of the heat dissipation cover of the outer side of the silicon substrate has a protrusion structure, and when the upper surface of the edge area of the reinforcement frame is mounted together with the lower surface of the bottom end of the cover rim of the heat dissipation cover of the outer side of the silicon substrate, the protrusion structure on the lower surface of the bottom end of the cover rim of the heat dissipation cover of the outer side of the silicon substrate is mounted in a corresponding groove structure of the upper surface of the edge area of the reinforcement frame by means of a bonding adhesive.

There are a flexible layer and a rigid layer located on the upper surface of the flexible layer.

### BRIEF DESCRIPTION OF THE DRAWINGS

FIG. 1 is a top view structural schematic diagram of a wafer-scale system in package structure in one embodiment of the present disclosure;

FIG. 2 is a cross-sectional structural schematic diagram in the direction of the cutting line AA1 in FIG. 1;

FIG. 3 is a cross-sectional structural schematic diagram in the direction of the cutting line BB1 in FIG. 1;

FIG. 4 is a structural schematic diagram of a wafer-scale system in package structure in another embodiment of the present disclosure;

FIG. 5 is a structural schematic diagram of a wafer-scale system in package structure in another embodiment of the present disclosure;

FIG. 6 shows a top view structural schematic diagram of a wafer-scale system in package structure in another embodiment of the present disclosure;

FIG. 7 is a cross-sectional structural schematic diagram in the direction of the cutting line AA1 in FIG. 6;

FIG. 8 is a cross-sectional structural schematic diagram of FIG. 6 after cutting off the edges; and

FIGS. 9-17 are structural schematic diagrams of the formation process of a wafer-scale system in package structure in one embodiment of the present disclosure.

### DETAILED DESCRIPTION OF EMBODIMENTS

Specific embodiments of the present disclosure are described in detail below in conjunction with the accompanying drawings. When detailing the embodiments of the present disclosure, the schematic drawings will not be partially enlarged in accordance with the general proportion for the convenience of illustration, and the schematic drawings are only examples, which shall not limit the scope of protection of the present disclosure herein. In addition, the three-dimensional spatial dimensions of length, width, and depth should be included in the actual production.

As the core-grain modules of the existing wafer-scale system in package structure develop into ultra-large size (greater than or equal to 300 mm) core-grain modules, warping adjustment of the wafer-scale system in package structure becomes an increasingly difficult challenge.

It is a problem to be solved by the present disclosure to provide a wafer-scale system in package structure and a method for forming the same to prevent warping of the wafer-scale system in package structure, so as to efficiently regulate warping of the system package structure of the wafer-scale ultra-large core-grain module at room temperature or at high temperature.

The advantages of the technical solution of the present disclosure lie in the following.

In the wafer-scale system in package structure and the method for forming the same in the aforementioned embodiments of the present disclosure, the package structure includes a silicon substrate; a plurality of functional sub-modules arranged in an array mounted on the upper surface of the silicon substrate, the plurality of functional sub-modules being electrically connected with the silicon substrate, and each of the functional sub-modules including four corner heads and edges located between adjacent corner heads; a warping and stress adjustment structure mounted on the upper surface of the silicon substrate at the edges of the functional sub-modules; a stress cushioning flexible member structure mounted on the upper surface of the silicon substrate at the corner heads of the functional sub-module; edge dummy devices of different sizes mounted on the upper surface of the edge area of the silicon substrate outside the array of the functional sub-modules; and a molding layer located on the upper surface of the silicon substrate, the molding layer covering the functional sub-modules, the warping and stress adjustment structure, the stress cushioning flexible member structure and edge dummy devices, the molding layer exposing the upper surface of the functional sub-modules, the warping and stress adjustment structure, the stress cushioning flexible member structure and edge dummy devices. By increasing the Si/EMC ratio within the wafer-scale system in package structure by the warping and stress adjustment structure, the overall warping of the wafer due to the smaller Si/EMC ratio of the wafer-scale system in package structure is reduced. Moreover, the stress cushioning flexible member structure can cushion and balance the larger stresses existing at the corner heads and near the corner heads of adjacent functional sub-modules, thereby reducing the warping of the wafer-scale system in package structure due to the large stresses existing at the corner heads of the functional sub-modules. Moreover, a plurality of edge dummy devices can be mounted on the upper surface of the edge area of the silicon substrate, thereby increasing the Si/EMC ratio of the edge area of the wafer-scale system in package structure, which, in turn, reduces the difference between the Si/EMC ratio of the edge area and the Si/EMC ratio of the intermediate area, thus effectively regulating the warping of the wafer-scale system in package structure of the ultra-large core-grain module at room temperature or at high temperature.

Furthermore, in one embodiment, the warping and stress adjustment structure includes a flexible layer and a rigid layer located on the upper surface of the flexible layer, and the rigidity of the flexible layer is smaller than the rigidity of the rigid layer. The warping and stress adjustment structure adopts a rigid-flexible double-layer stacked structure. On the one hand, the rigid-flexible double-layer stacked structure can increase the Si/EMC ratio within the wafer-scale system in package structure, and on the other hand, the rigid-flexible double-layer stacked structure can broaden the application range of the warping and stress adjustment structure.

Furthermore, in one embodiment, at least two of the warping and stress adjustment structures are provided on the upper surface of the silicon substrate at each edge of the functional sub-module, which can avoid the aspect ratio of the warping and stress adjustment structures from being too large, thus reducing the difficulty of manufacturing the suction nozzles (the suction nozzles are used to adsorb the warping and stress adjustment structures when mounting) and the difficulty of the mounting process when mounting the warping and stress adjustment structures, while avoiding stress and warping problems introduced by the too large aspect ratio of the warping and stress adjustment structures.

Furthermore, in one embodiment, when the warping and stress adjustment structure is mounted in a floating manner on the upper surface of the silicon substrate, on the one hand, the warping and stress adjustment structure can increase the Si/EMC ratio within the wafer-scale system in package structure, on the other hand, between the lower surface of the floating warping and stress adjustment structure and the upper surface of the silicon substrate, there is a gap, and the height of the gap can be adjusted by adjusting the spacing between adjacent functional sub-modules, thereby adjusting the height difference between the upper surface and the lower surface of the warping and stress adjustment structure that can be filled with molding material, which further extends the application range of the warping and stress adjustment structure.

Furthermore, in one embodiment, the stress cushioning flexible member structure includes a first cushioning layer, a core layer located on the upper surface of the first cushioning layer, and a second cushioning layer located on the upper surface of the core layer, the second cushioning layer and the core layer having in them blind holes running through the second cushioning layer and the core layer, on the one hand, the rigidity of the stress cushioning flexible member structure of the structure is smaller, thereby more effectively cushioning and balancing larger stresses which exist at the corner heads and near the corner heads of adjacent functional sub-modules, on the other hand, when a heat dissipation cover is mounted on the upper surfaces of the molding layer, the functional sub-modules, the warping and stress adjustment structure and the stress cushioning flexible member structure and on the outer sides of the molding layer and the silicon substrate, the stress cushioning flexible member structure provides support and cushioning pads on the lower surface of the heat dissipation cover, and provides a mounting interface for the anchoring protrusions on the lower surface of the horizontal cover top of the heat dissipation cover, and at the same time, when the heat dissipation cover is mounted, the anchoring protrusions on the lower surface of the horizontal cover top of the heat dissipation cover are correspondingly mounted in corresponding blind holes, i.e., the blind holes also provide a limiting space for the anchoring protrusions on the lower surface of the horizontal cover top of the heat dissipation cover, which improves the alignment accuracy of the heat dissipation cover when mounting, and limits the mounting accuracy of the heat dissipation cover during the mounting process and the bonding process of the heat dissipation cover, and when the anchoring protrusions on the lower surface of the horizontal cover top of the heat dissipation cover are correspondingly mounted in the corresponding blind holes, the anchoring protrusions are locked in the blind holes, which improves the firmness of mounting the heat dissipation cover.

Furthermore, in one embodiment, the package structure further includes: a reinforcement frame mounted on a lower surface of the silicon substrate, and an upper surface of an edge area of the reinforcement frame is mounted together with a lower surface of a bottom end of the cover rim of the heat dissipation cover of an outer side of the silicon substrate. The reinforcement frame has in it a plurality of carving holes, the carving holes exposing a portion of the second redistribution layer. By means of the reinforcement frame, on the one hand, it serves to protect the lower surface of the silicon substrate, and on the other hand, by coordinating from the lower surface of the silicon substrate with the upper surface and lateral surface of the silicon substrate and the heat dissipation cover, it further adjusts and controls warping of the wafer-scale system in package structure, on yet another hand, the carving holes provide limiting slots for the next level package and assembly to improve the accuracy of the mounting and alignment of the next level package and assembly.

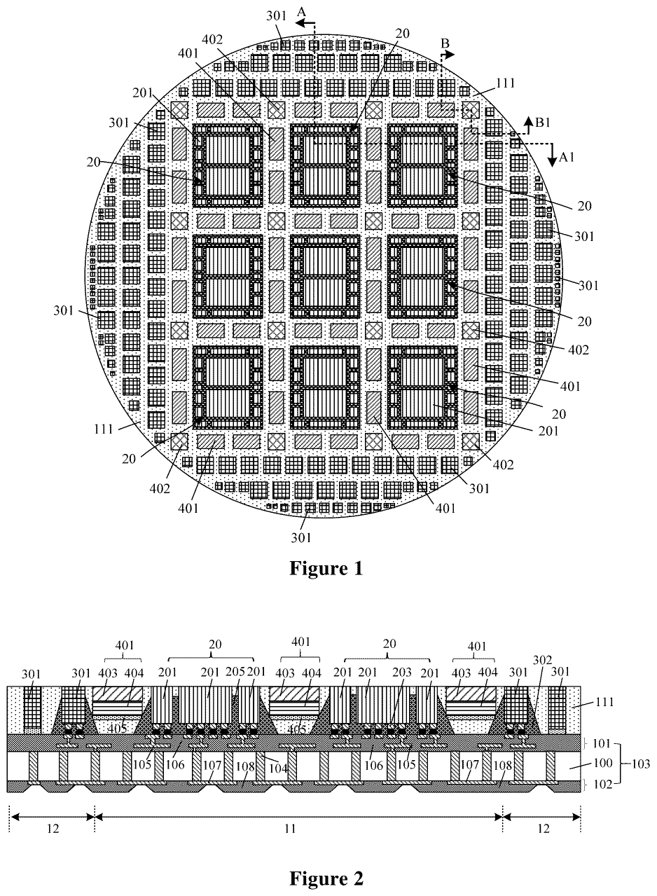

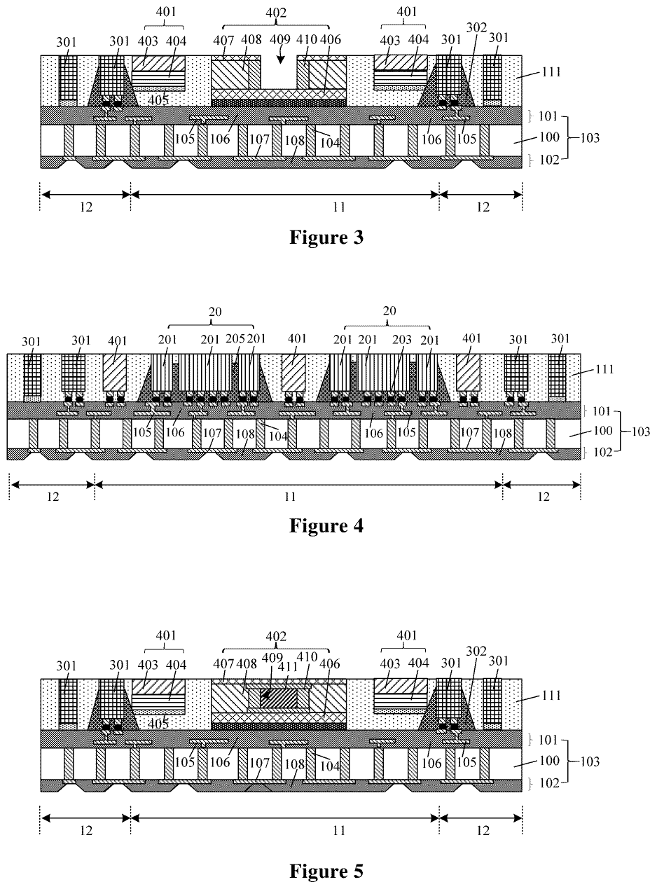

An embodiment of the present disclosure firstly provides a system in package structure, with reference to FIGS. 1-3, wherein FIG. 2 is a cross-sectional structural schematic diagram in the direction of the cutting line AA1 in FIG. 1, FIG. 3 is a cross-sectional structural schematic diagram in the direction of the cutting line BB1 in FIG. 1, including: a silicon substrate 103, the silicon substrate 103 including opposed upper surface and lower surface; a plurality of functional sub-modules 20 mounted on the upper surface of the silicon substrate 103 arranged in an array, the plurality of functional sub-modules 20 being electrically connected with the silicon substrate 103, and each of the functional sub-modules 20 including four corner heads and edges located between adjacent corner heads; a warping and stress adjustment structure 401 mounted on the upper surface of the silicon substrate 103 at the edge of the functional sub-module 20; a stress cushioning flexible member structure 402 mounted on the upper surface of the silicon substrate 103 at the corner heads of the functional sub-module 20; edge dummy devices 301 of different sizes mounted on the upper surface of the edge area of the silicon substrate 103 outside the array of the functional sub-modules 20; and a molding layer 111 located on the upper surface of the silicon substrate 103, the molding layer covering the functional sub-modules 20, the warping and stress adjustment structure 401, the stress cushioning flexible member structure 402 and edge dummy devices 301, the molding layer 111 exposing the upper surface of the functional sub-modules 20, the warping and stress adjustment structure 401, the stress cushioning flexible member structure 402 and edge dummy devices 301.

Specifically, the silicon substrate 103 includes a silicon wafer body 100, a first redistribution layer 101 located on the upper surface of the silicon wafer body 100 and a second redistribution layer 102 located on the lower surface of the silicon wafer body 100.

The material of the silicon wafer body 100 is silicon, the silicon wafer body 100 may be circular or square, and the shape of the silicon substrate 103 is correspondingly circular or square. In the present embodiment, the package structure is a wafer-scale system in package structure, and the dimension of the wafer-scale system in package structure is larger, and accordingly the dimensions of the silicon wafer body 100 and silicon substrate 103 will also be larger. In a specific embodiment, when the silicon wafer body 100 and silicon substrate 103 are circular, the diameter dimensions of the silicon wafer body 100 and silicon substrate 103 may be 300 mm, 450±5 mm, and when the silicon wafer body 100 and silicon substrate 103 are square, the diagonal dimensions of the silicon wafer body 100 and silicon substrate 103 may be 300 mm, 450±10 mm.

In one embodiment, the silicon wafer body 100 has through-silicon-vias 104 and micro-devices (not shown in the figures), the through-silicon-vias 104 being electrically connected with the first redistribution layer 101 and the second redistribution layer 102. In a specific embodiment, the through-silicon-vias 104 are located in the silicon wafer body and the through-silicon-vias 104 run through the upper surface and lower surface of the silicon wafer body 100, the upper ends of the through-silicon-vias 104 are electrically connected with the first redistribution layer 101, and the lower ends of the through-silicon-vias 104 are electrically connected with the second redistribution layer 102, and the material of the through-silicon-vias 104 is metal, specifically may be one or more of Al, Cu, W, Au, Ag, Pt, Ni, Ti, Ta, TiN, TaN, TaC, WN. The micro-device may be electrically connected with the first redistribution layer 101, and the micro-device in conjunction with the first redistribution layer 101 (and second redistribution layer 102) may constitute a circuit with a specific function, the specific function may be one or more of decoupling and voltage stabilization of signals, anti-static and over-voltage protection, or signal filtering, the specific function may also include other suitable functions. The micro-device may be formed inside the silicon wafer body 100 and/or on the upper surface of the silicon wafer body by a semiconductor integrated manufacturing process. In one embodiment, the micro-device is one or more of a Deep Trench Capacitor (DTC), a diode for protection, and a grounding inductor, the high density trench silicon capacitor may be used for decoupling and voltage stabilization, the diode for protection may be used for anti-static and over-voltage protection, and the grounding inductor may be used for signal filtering or isolation.

The first redistribution layer 101 is located on the upper surface of the silicon wafer body 100. In one embodiment, the first redistribution layer 101 includes a first passivation layer 106 located on the upper surface of the silicon wafer body 100 and a first line 105 located in the first passivation layer 106, when the through-silicon-via 104 is electrically connected with the first redistribution layer 101 and the functional sub-module 20 is electrically connected with the silicon substrate 103, both the through-silicon-via 104 and the functional sub-module 20 are electrically connected with the corresponding first line 105 in the first redistribution layer 101. In a specific embodiment, the first passivation layer 106 may be a single-layer or multi-layer stacked structure, and correspondingly, the first line 105 may be a single-layer or multi-layer line structure. The material of the first passivation layer 106 may be an inorganic material or an organic material, the inorganic material may be one or more of silicon oxide, silicon nitride, silicon nitride oxide, silicon carbon oxide, silicon carbon nitride, and the organic material may be a polymer resin material, which specifically may include an epoxy resin, a polyimide resin, a benzocyclobutene resin or a polybenzoxazole resin. The material of the first line 105 is a metal, and specifically may be one or more of Al, Cu, W, Au, Ag, Pt, Ni, Ti, Ta, TiN, TaN, TaC, WN. In a specific embodiment, the first passivation layer 106 is a double-layer stacked structure, including an inorganic material passivation layer located on the upper surface of the silicon wafer body 100 and an organic material passivation layer located on the upper surface of the inorganic material passivation layer.

The second redistribution layer 102 is located on the lower surface of the silicon wafer body 100. In one embodiment, the second redistribution layer 102 includes a second passivation layer 108 located on the lower surface of the silicon wafer body 100 and a second line 107 located in the second passivation layer 108, and when the through-silicon-via 104 is electrically connected with the second redistribution layer 102, the through-silicon-via 104 is electrically connected with the corresponding second line 107 in the second redistribution layer 102. In a specific embodiment, the second passivation layer 108 may be a single-layer or multi-layer stacked structure, and correspondingly, the second line 107 may be a single-layer or multi-layer line structure. The material of the second passivation layer 108 may be an inorganic material or an organic material, the inorganic material may be one or more of silicon oxide, silicon nitride, silicon nitride oxide, silicon carbon oxide, silicon carbon-nitride, and the organic material may be a polymer resin material, which specifically may include an epoxy resin, a polyimide resin, a benzocyclobutene resin or a polybenzoxazole resin. The material of the second line 107 is a metal, and specifically may be one or more of Al, Cu, W, Au, Ag, Pt, Ni, Ti, Ta, TiN, TaN, TaC, WN. In a specific embodiment, the second passivation layer 108 is a double-layer stacked structure, including an inorganic material passivation layer located on the lower surface of the silicon wafer body 100 and an organic material passivation layer located on the surface of the inorganic material passivation layer.

In one embodiment, the silicon substrate 103 may include an intermediate area 11 and an edge area 12 surrounding the intermediate area 11, the plurality of functional sub-modules 20, the warping and stress adjustment structure 401, and the stress cushioning flexible member structure 402 being all mounted on the upper surface of the intermediate area 11.

It is unable to mount, on the edge area 12 of the silicon substrate 103, the functional sub-module 20 due to its small width, and when the upper surface of the edge area 12 is fully covered by the molding layer 111, there is no silicon material on the upper surface of the edge area 12, and the Si/EMC ratio is small (Si is silicon, and EMC is the molding material), and on the upper surface of the intermediate area 11, a functional sub-module is mounted, i.e., most of the intermediate area is silicon material, and a small portion is a molding layer material, and the Si/EMC ratio of the intermediate area 11 is large, which can lead to the formation of warping in the wafer-scale system in package structure due to a large difference in the Si/EMC ratio between the edge area 12 and the intermediate area 11. Therefore, in one embodiment, a plurality of edge dummy devices 301 may be mounted on the upper surface of the edge area 12, thereby increasing the Si/EMC ratio of the edge area 12 of the wafer-scale system in package structure, thereby reducing the difference between the Si/EMC ratio of the edge area 12 and the Si/EMC ratio of the intermediate area 11, so as to effectively regulate the warping of the system in package structure of the wafer-scale ultra-large core-grain module at room temperature or at high temperature.

In one embodiment, the edge dummy device 301 may be one or more of a passive device, a heat dissipation discrete member, or a dummy piece. In a specific embodiment, when the edge dummy device 301 mounted on the upper surface of the edge area of the silicon substrate 103 is a passive device, the passive device may be electrically connected with the silicon substrate 103, and the passive device may be one or more of a resistor, a capacitor, or an inductor. In another specific embodiment, when the edge dummy device 301 mounted on the upper surface of the edge area of the silicon substrate 103 is a heat dissipation discrete member, such as a heat dissipation metal block, the lower surface of the heat dissipation discrete member is adhered on the upper surface of the edge area 12 of the silicon substrate 103 by means of a heat dissipation adhesive, and the heat dissipation discrete member can be used for heat dissipation of the package structure, and the material of the heat dissipation discrete member is a metallic material used for heat dissipation. In another specific embodiment, when the edge dummy device 301 mounted on the upper surface of the edge area of the silicon substrate 103 is a dummy piece, the lower surface of the dummy is adhered to the upper surface of the edge area 12 of the silicon substrate 103 by means of an adhesive, and the dummy is a silicon grain without lines.

In one embodiment, the dimension of the edge dummy device 301 far away from the intermediate area 11 is smaller than the dimension of the edge dummy device 301 close to the intermediate area 11. So that the upper surface of the edge area 12 is sufficiently mounted on the edge device 301, thereby further increasing the Si/EMC ratio of the edge area 12 of the wafer-scale system in package structure, and thus further reducing the difference between the Si/EMC ratio of the edge area 12 and the Si/EMC ratio of the intermediate area 11, which is conducive to better suppressing the warping of the wafer-scale system in package structure.

In one embodiment, the edge dummy device 301 mounted on the upper surface of a portion of the edge area 12 close to the intermediate area 11 is a passive device or a dummy piece, and the edge dummy device 301 mounted on the upper surface of a portion of the edge area 12 far away from the intermediate area 11 is a heat dissipation discrete device or a dummy piece; on the one hand, the mounting manner of the passive device or the dummy piece (edge dummy device 301) close to the intermediate area 11 can be the same as the mounting manner of the functional sub-module 20 to maintain consistency of the mounting manner; on the other hand, between the passive device or the dummy piece (edge dummy device 301) close to the intermediate area 11 and the upper surface of the silicon substrate 103 as well as the sidewalls of the passive device or the dummy piece (edge dummy device 301), an underfill layer 302 (referring to FIG. 2 or FIG. 3) can be covered, and when on the upper surface of the silicon substrate 103 on the outside edge of the outermost functional sub-module 20, a warping and stress adjustment structure 401 is mounted, the warping and stress adjustment structure 401 can be floatingly mounted on the edge sidewall surface of the outermost functional sub-module 20 and the inclined sidewall surface of the underfill layer 302 on the sidewall surface of the passive device or dummy piece (edge dummy device 301) (the two warping and stress adjustment structures 401 located on two sides as shown in FIG. 2).

In one embodiment, if a plurality of edge dummy devices 301 are mounted on the upper surface of the edge area 12 of the silicon substrate 103, then the edge devices may be arranged in rows or columns.

The functional sub-module 20 is a chip module having a specific function. A plurality of functional sub-modules 20 are mounted in an array on the upper surface of the silicon substrate 103. The number of the functional sub-modules 20 is at least two, specifically 2, 4, 9, 16, 25 or more (e.g., N², N is greater than 5), and a plurality of functional sub-modules 20 may be mounted on the upper surface of the silicon substrate 103 in an array of A×B (A need not be equal to B) such as 1×1, 2×2, 3×3, 4×4, 5×5, etc., or in a greater number of arrays. As shown in FIG. 1, nine functional sub-modules 20 are arranged in a 3×3 array and mounted on the upper surface of the silicon substrate 103 as an example.

In one embodiment, each of the functional sub-modules 20 has the same structure and the same function, the planar layout of each of the functional sub-modules 20 may be in the form of a rectangle or a square, and each of the functional sub-modules 20 includes four corner heads and edges located between adjacent corner heads, i.e., includes four corner heads and four edges. In other embodiments, the planar layout of the functional sub-modules 20 may be in other shapes, such as rectangle-like, square-like, parallelogram, or other regular shapes. In one embodiment, each of the sub-modules 20 includes at least two (≥2) semiconductor chips 201. In a specific embodiment, when each of the sub-modules 20 includes a plurality of semiconductor chips 201, the dimensions and/or functions of the plurality of semiconductor chips 201 are different. In another specific embodiment, when each of the sub-modules 20 includes a plurality of semiconductor chips 201, the dimensions and/or functions of some number of semiconductor chips 201 may be the same, and the dimensions and/or functions of some number of semiconductor chips 201 may be different. In one embodiment, the semiconductor chip 201 includes, but is not limited to, a signal processing chip, a logic control chip, a memory chip, a sensor chip, a power supply chip, or a radio frequency chip.

The semiconductor chip 201 in each of the functional sub-modules 20 is mounted on the upper surface of the silicon substrate 103 by means of flip-flop manner. In one embodiment, the semiconductor chip 201 includes opposed active surface and back surface, the active surface having solder bumps 203, and in the semiconductor chip 201, an integrated circuit (not shown in the FIG) with a specific function is formed, the solder bumps 203 being electrically connected with the integrated circuit. When the semiconductor chip 201 is mounted on the upper surface of the silicon substrate 103 by means of flip-flop manner, the active surface of the semiconductor chip 201 is facing downwards, and the solder bumps 203 on the active surface are soldered with the corresponding first lines 105 in the first redistribution layer 101 of the silicon substrate 103. In one embodiment, the solder bump 203 may include a pad and a solder layer located on the surface of the pad, and in another embodiment, the solder bump 203 may also include a pad, a metal pillar located on the surface of the pad, and a solder layer located on the top surface of the metal pillar. The material of the pad and metal pillar is metal and may be one or more of aluminum, copper, nickel, tin, titanium, tungsten, platinum, chromium, tantalum, gold, or silver. The material of the solder layer is tin or tin alloy, the tin alloy being one or more of tin-silver, tin-zinc, tin-lead, tin-indium, tin-gold, tin-copper, tin-silver-copper, tin-silver-zinc, tin-bismuth-indium, tin-zinc-indium, or tin-silver-antimony.

In one embodiment, each of the functional sub-modules 20 further includes an underfill layer 205 filled between the lower surface (active surface) of the semiconductor chip 201 in each of the functional sub-modules 20 and the upper surface of the silicon substrate 103 and covering the sides of the semiconductor chip 201. In one embodiment, the underfill layer 205 may cover a portion or all of the sidewalls of the semiconductor chip 201. The underfill layer 205 on the sidewall surface of the semiconductor chip 201 has an inclined sidewall, and in one embodiment, the warping and stress adjustment structure 401 can be floatingly mounted on the surface of the sidewall of the functional sub-module 20 (a warping and stress adjustment structure 401 located in the middle, as shown in FIG. 2) (the sidewall of functional sub-module 20 is the inclined sidewall of the underfill layer 205) by means of a bonding adhesive, i.e., so that the warping and stress adjustment structure 401 can be floatingly mounted above the upper surface of the silicon substrate 103.

In the present disclosure, on the upper surface of the silicon substrate 103 at the edge of the functional sub-module 20, the Si/EMC ratio within the wafer-scale system in package structure is increased by the warping and stress adjustment structure 401, thereby reducing the overall warping of the wafer due to the small Si/EMC ratio of the wafer-scale system in package structure. And at the same time, a stress cushioning flexible member structure 402 is mounted on the upper surface of the silicon substrate 103 between the corner heads of the adjacent functional sub-modules 20 and outside the corner head of the outermost functional sub-module 20, the stress cushioning flexible member structure 402 can cushion and balance the larger stress existing at the corner heads and near the corner heads of the adjacent functional sub-modules 20, and thus reduce the overall warping of the wafer-scale system in package structure due to the presence of larger stresses at the corner heads of the functional sub-modules 20.

The number of the warping and stress adjustment structures 401 is multiple, some of the warping and stress adjustment structures 401 are mounted on the upper surface of the silicon substrate 103 between the edges of the adjacent functional sub-modules 20, and some of the warping and stress adjustment structures 401 are mounted on the upper surface of the silicon substrate 103 on the outside of the edges of the outermost functional sub-module 20. In one embodiment, the number of the warping and stress adjustment structures 401 mounted on the upper surface of the silicon substrate 103 of each edge of the functional sub-module 20 is at least two, and the plurality of the warping and stress adjustment structures 401 are arranged in a direction parallel to the edges of the functional sub-module 20, and two of the warping and stress adjustment structures 401 are mounted on the upper surface of the silicon substrate 103 of each edge of the functional sub-module 20 as shown in FIG. 1. At least two of the warping and stress adjustment structures 401 are provided on the upper surface of the silicon substrate 103 on each edge side of the functional sub-module 20, which can avoid the aspect ratio of the warping and stress adjustment structures 401 from being too large, thus reducing the difficulty of manufacturing the suction nozzles (the suction nozzles are used to adsorb the warping and stress adjustment structures 401 when mounting) and the difficulty of the mounting process when mounting the warping and stress adjustment structures 401, while avoiding stress and warping problems introduced by the too large aspect ratio of the warping and stress adjustment structures 401.

In one embodiment, referring to FIG. 2 or FIG. 3, the warping and stress adjustment structure 401 includes a flexible layer 404 and a rigid layer 403 located on the upper surface of the flexible layer 404, and the rigidity of the flexible layer 404 is smaller than the rigidity of the rigid layer 403. The warping and stress adjustment structure 401 adopts a rigid-flexible double-layer stacked structure. On the one hand, the rigid-flexible double-layer stacked structure can increase the Si/EMC ratio within a wafer-scale system in package structure, and on the other hand, the rigid-flexible double-layer stacked structure can broaden the application range of the warping and stress adjustment structure 401.

In one embodiment, the material of the rigid layer 403 is silicon, germanium silicon, or silicon carbide, and the material of the flexible layer 404 is at least one of a filler and fiber-filled polymer composite material, which may be specifically an epoxy resin molding material, a thermosetting epoxy resin film, and a semi-cured laminated epoxy resin sheet.

The warping and stress adjustment structure 401 of the rigid-flexible double-layer stacked structure is mounted on the upper surface of the silicon substrate 103 in two ways, including direct contact mounted on the upper surface of the silicon substrate 103 and floatingly mounted on the upper surface of the silicon substrate 103. In one embodiment, and continuing to refer to FIG. 2, when a floating mounting is carried out, a portion of the warping and stress adjustment structure 401 is floatingly mounted on the sidewall surface of an adjacent functional sub-module 20 by means of a bonding adhesive 405, and, specifically, the warping and stress adjustment structure 401 is floatingly mounted on the side of an inclined sidewall of the underfill layer 205 on the side of an adjacent functional sub-module 20 by means of a bonding adhesive 405 (the warping and stress adjustment structure 401 located in the middle as shown in FIG. 3), and continuing to refer to FIG. 2, a portion of the stress adjustment structure 401 is floatingly mounted on the inclined sidewall surface of the underfill layer 302 on the edge sidewall surface of the outermost functional sub-module 20 and the sidewall surface of the edge dummy device 301 near the intermediate area 11 (the warping and stress adjustment structure 401 located on the two sides as shown in FIG. 2). When the warping and stress adjustment structure 401 is floatingly mounted, on the one hand, the warping and stress adjustment structure 401 can increase the Si/EMC ratio within the wafer-scale system in package structure, and on the other hand, the lower surface of the floating warping and stress adjustment structure 401 and the upper surface of the silicon substrate 103 have between them a gap, the height of this gap can be adjusted by adjusting the spacing between adjacent functional sub-modules 20, thereby adjusting the height difference between the fillable molding material on the upper surface and lower surface of the warping and stress adjustment structure, which further extends the application range of the warping and stress adjustment structure 401.

In another embodiment, when direct contact mounting is performed, the warping and stress adjustment structure 401 is directly mounted on the upper surface of the silicon substrate 103 between the edges of the adjacent functional sub-modules 20 and on the upper surface of the silicon substrate 103 outside of the edges of the outermost functional sub-modules 20 by means of the bonding adhesive 405.

In another embodiment, the warping and stress adjustment structure 401 may be other structures, with reference to FIG. 4, and the warping and stress adjustment structure 401 may be one or more of a flip chip, a surface mount device, a functional device, a structural dummy piece, or a heat dissipation dummy piece. The surface mount device may be a surface mount passive device. The functional device may be an Integrated Passive Device (IPD), a Deep Trench Capacitor (DTC), a Bridgel/ODie, a logic chip, or a Multi-Layer Ceramic Capacitor (MLCC). The warping and stress adjustment structure 401 is soldered on the upper surface of the silicon substrate 103 by means of a solder layer, and the warping and stress adjustment structure 401 is electrically connected with the silicon substrate 103. When the warping and stress adjustment structure 401 is a structural dummy piece or a heat dissipation dummy piece, the lower surface of the warping and stress adjustment structure 401 is adhered and mounted on the upper surface of the silicon substrate 103 by means of the bonding adhesive.

Continuing to refer to FIG. 1 and FIG. 3, the rigidity of the stress cushioning flexible member structure 402 is smaller, such that the stress cushioning flexible member structure 402 can effectively cushion and balance the larger stresses existing at the corner heads and near the corner heads of adjacent functional sub-modules 20, thereby effectively reducing warping of the wafer-scale system in package structure due to the larger stresses existing at the corner heads of the functional sub-modules 20.

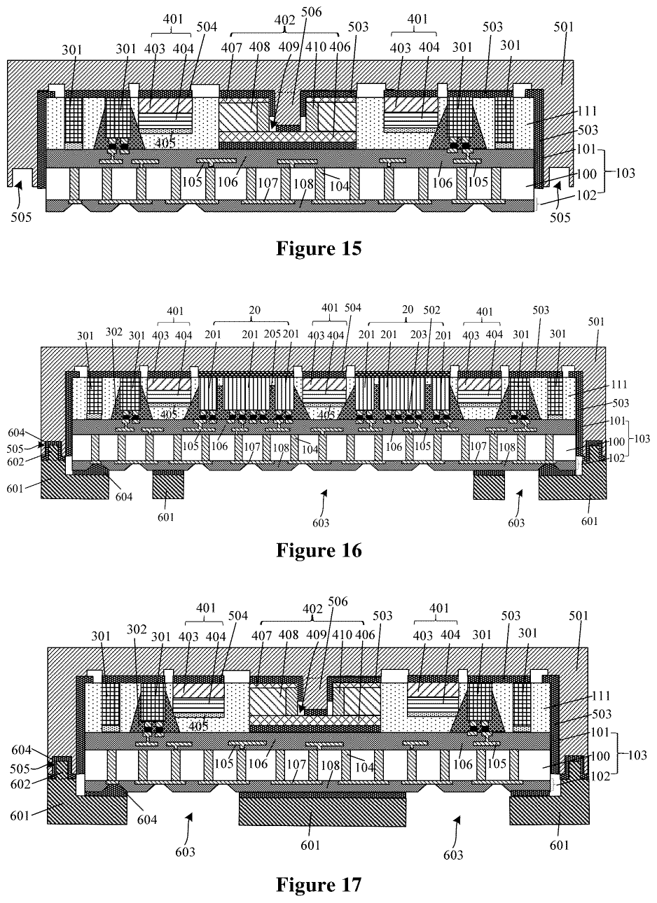

In one embodiment, the stress cushioning flexible member structure 402 includes a first cushioning layer 406, a core layer 408 located on the upper surface of the first cushioning layer 406, and a second cushioning layer 407 located on the upper surface of the core layer 408, the second cushioning layer 407 and the core layer 408 having in them blind holes 409 running through the second cushioning layer 407 and the core layer 408, on the one hand, the rigidity of the stress cushioning flexible member structure 402 of the structure is smaller, thereby more effectively cushioning and balancing larger stresses that exist at the corner heads and near the corner heads of adjacent functional sub-modules 20, on the other hand, when a heat dissipation cover 501 (referring to FIG. 15) is mounted on the upper surfaces of the molding layer 111, the functional sub-modules 20, the warping and stress adjustment structure 401 and the stress cushioning flexible member structure 402 as well as on the outer sides of the molding layer111 and the silicon substrate 103, the stress cushioning flexible member structure 402 provides a support and cushioning pads on the lower surface of the horizontal cover top of the heat dissipation cover 501, and provides a mounting interface for the anchoring protrusions 506 on the lower surface of the horizontal cover top of the heat dissipation cover 501, and at the same time, when the heat dissipation cover 501 is mounted, the anchoring protrusions 506 on the lower surface of the horizontal cover top of the heat dissipation cover 501 are correspondingly mounted in corresponding blind holes 409, i.e., the blind holes 409 also provide a limiting space for the anchoring protrusions 506 on the lower surface of the horizontal cover top of the heat dissipation cover 501, which improves the alignment accuracy of the heat dissipation cover when mounting, and defines the mounting accuracy of the heat dissipation cover 501 during the mounting process and the bonding process of the heat dissipation cover 501, and when the anchoring protrusions 506 on the lower surface of the horizontal cover top of the heat dissipation cover 501 are correspondingly mounted in the corresponding blind holes 409, the anchoring protrusions 506 are locked in the blind holes, which improves the firmness of the mounting of the heat dissipation cover.

In one embodiment, the first cushioning layer 406 and the second cushioning layer 407 are used for stress cushioning between the upper surface and lower surface of the stress cushioning flexible member structure 402 and other structures. The material of the first cushioning layer 406 and second cushioning layer 407 is an organic or inorganic cushion material, and the material of the core layer 408 is a PCB or substrate material.

In another embodiment, referring to FIG. 5, the stress cushioning flexible member structure 402 includes a first cushioning layer 406, a core layer 408 located on the surface of the first cushioning layer 406, and a second cushioning layer 407 located on the surface of the core layer 408, the core layer 408 having in it blind holes 409, and a portion of the lower surface of the heat dissipation cover 501 is mounted on the surface of the second cushioning layer 407 by means of a bonding adhesive. Inside the blind holes 409, there are cavities, or the blind holes 409 are fully filled with filler material 411 (referring to FIG. 5), and when mounting the heat dissipation cover 501 subsequently, a portion of the lower surface of the horizontal cover top of the heat dissipation cover 501 is mounted on the upper surface of the second cushioning layer 407 in the stress cushioning flexible member structure 402 by means of a bonding adhesive. In addition to more effectively cushioning and balancing the higher stresses that exist at the corner heads and near the corner heads of the adjacent functional sub-modules 20, the stress cushioning flexible member structure 402 also provides support and cushioning pads for the lower surface of the horizontal cover top of the heat dissipation cover 501.

In one embodiment, with reference to FIG. 3 or FIG. 5, the sidewall surface of the blind hole 409 further has a metal layer 410. In one embodiment, with reference to FIG. 5, when the blind hole 409 is filled with a filler material 411, in addition to the sidewall surface of the blind hole 409 further having a metal layer 410, the top and the bottom of the filler material 411 further have a metal layer.

The number of the stress cushioning flexible member structures 402 is multiple, and a stress cushioning flexible member structure 402 is mounted on the upper surface of the silicon substrate 103 at the corner head of each of the chip sub-modules 20.

With continuing to refer to FIGS. 1-3, it further includes: a molding layer 111 located on the upper surface of the silicon substrate 103 covering the functional sub-module 20, the warping and stress adjustment structure 401, the stress cushioning flexible member structure 402, and the edge dummy device 301, the molding layer 111 exposing the upper surface of the functional sub-module 20, the warping and stress adjustment structure 401, the stress cushioning flexible member structure 402, and the edge dummy device 301.

The material of the molding layer 111 may be a filler-containing epoxy resin, a polyimide resin, a benzocyclobutene resin, or a polybenzoxazole resin; or it may also be a filler-containing polybutylene terephthalate, polycarbonate, polyethylene terephthalate, polyethylene, polypropylene, polyolefin, polyurethane, polyethersulfone, polyamide, polyimide, ethylene vinyl acetate copolymer, or polyvinyl alcohol. In some embodiments, the filler may be an inorganic filler or an organic filler. In some embodiments, the process for forming the molding layer 111 includes a compression molding process (Compression Molding) or a transfer molding process (Transfer Molding).

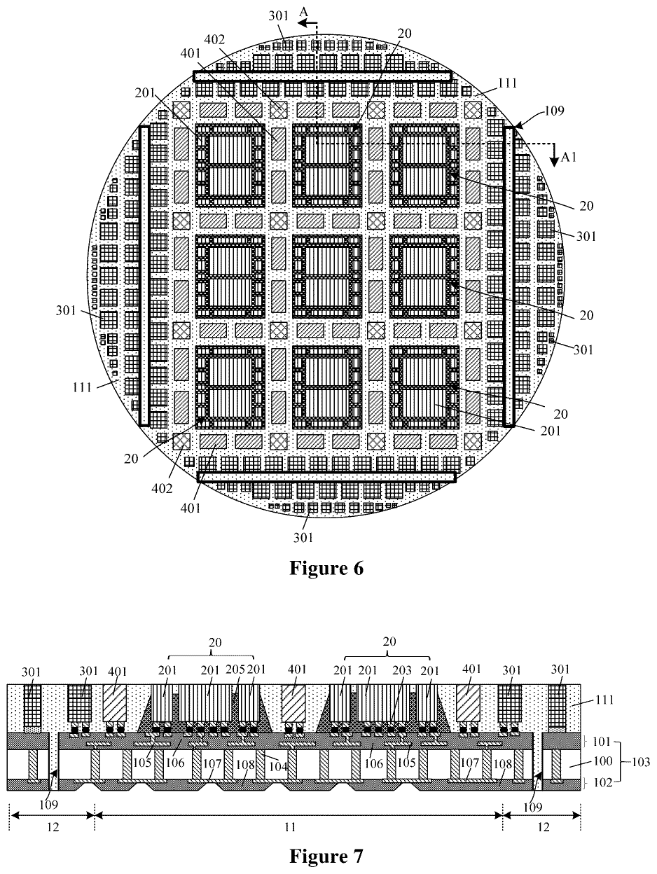

In one embodiment, referring to FIG. 6 and FIG. 7, FIG. 7 is a cross-sectional structural schematic diagram in the direction of the cutting line AA1 in FIG. 6, the silicon substrate 103 of the edge area 12 further has in it a trench 109, the trench 109 running through or not running through the silicon substrate 103, and the molding layer 111 also fully fills the trench 109. By means of the trench 109, the warping and stresses in the edge area 12 of the silicon substrate 103 can be released, thereby reducing warping in wafer-scale system in package structures. The depth of the trenches 109 may vary according to different process requirements.

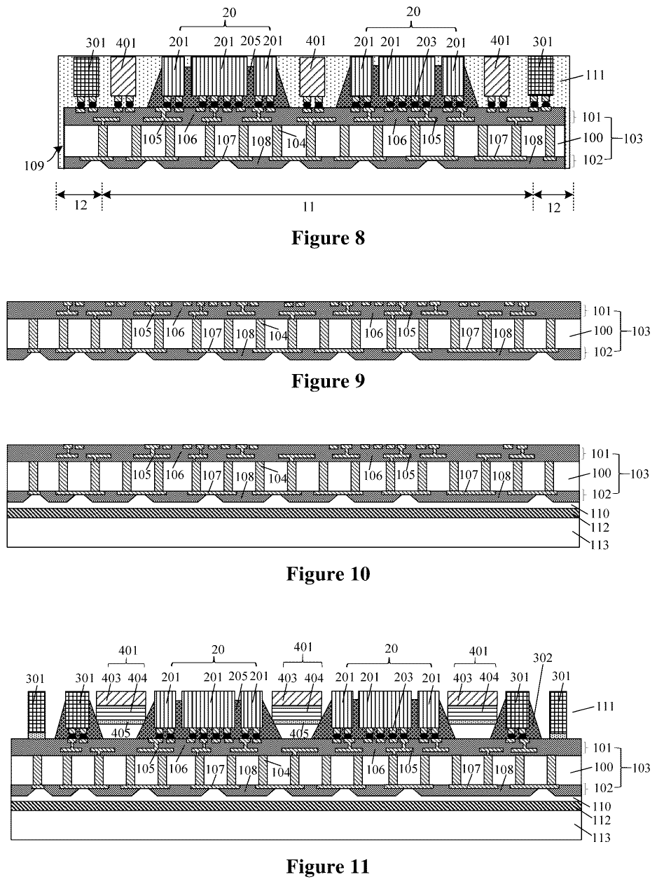

In one embodiment, the trenches 109 are formed in the silicon substrate 103 between adjacent edge dummy devices 301. In one embodiment, for a circular silicon substrate 103, the number of the trenches 109 may be four, and they are respectively located in four edge areas 12 around the intermediate area 11 of the silicon substrate 103, the trenches 109 extending along a longitudinal direction in the edge areas 12 on the left and right sides of the intermediate area 11, the trenches 109 extending along a transversal direction in the edge areas 12 on the upper and lower sides of the intermediate area 11. Subsequently, the four edges of the packaged structure can be cut along the four trenches 109 to form a square-shaped wafer-scale system in package structure (referring to FIG. 8).

In one embodiment, with reference to FIG. 14 and FIG. 15, the FIG. 14 and FIG. 15 are structures obtained on the basis of FIG. 2 and FIG. 3, respectively, the package structure further includes: a heat dissipation cover 501 mounted on the upper surfaces of the molding layer 111, the functional sub-module 20, the warping and stress adjustment structure 401, and the stress cushioning flexure member structure 402, as well as on the outer sides of the molding layer 111 and the silicon substrate 103.

The heat dissipation cover 501 is used to dissipate heat from a wafer-scale system in package structure. The heat dissipation cover 501 includes a horizontal cover top and a cover rim protruding from the lower surface of an edge of the horizontal cover top, and the lower surface of the horizontal cover top is horizontal or has an optional downward protrusion in a corresponding area of the functional sub-module, the warping and stress adjustment structure, and the stress cushion flexible member structure. The lower surface of the horizontal cover top of the heat dissipation cover 501 is mounted on the upper surface of the molding layer 111, the functional sub-module 20, the warping and stress adjustment structure 401 and the stress cushioning flexible member structure 402, and the surface of the inner wall of the cover rim of the heat dissipation cover 501 is mounted on the outer side surfaces of the molding layer 111 and the silicon substrate 103. In specific embodiments, a portion of the lower surface of the horizontal cover top of the heat dissipation cover 501 is mounted on the upper surface of the molding layer 111 and the stress cushioning flexible member structure 402 by means of a bonding adhesive 503, and a portion of the lower surface of the horizontal cover top of the heat dissipation cover 501 is mounted on the upper surface of the functional sub-module 20 by means of a heat dissipation adhesive 502, and a portion of the lower surface of the horizontal cover top of the heat dissipation cover 501 is mounted on the upper surface of the warping and stress adjustment structure 401 by means of a bonding adhesive 503 or a heat dissipation adhesive 504, and the vertical inner sidewall surface of the cover rim of the heat dissipation cover 501 is mounted on the outer side surfaces of the molding layer 111 and the silicon substrate 103 by means of a bonding adhesive 503.

In one embodiment, referring to FIG. 15, the lower surface of the horizontal cover top of the heat dissipation cover 501 has a plurality of downwardly protruding anchoring protrusions 506, the anchoring protrusions 506 being mounted in corresponding blind holes 409 by means of bonding adhesive 503. In one embodiment, the material of the heat dissipation cover 501 is a material having a high thermal conductivity, including a metal (e.g., copper, aluminum, gold, nickel, steel, or stainless steel) or a carbon-containing material (e.g., graphite, graphene, or carbon nanotubes).

In one embodiment, with reference to FIG. 16 and FIG. 17, FIG. 16 and FIG. 17 are structures obtained on the basis of FIG. 14 and FIG. 15, respectively, the package structure further includes: a reinforcement frame 601 mounted on the lower surface of the silicon substrate 103, and the upper surface of the edge area of the reinforcement frame 601 is mounted together with the lower surface of the bottom end of the cover rim of the heat dissipation cover 501 on the outer side of the silicon substrate 103. The reinforcement frame 601 has in it a plurality of carving holes 603, the carving holes 603 exposing a portion of the second redistribution layer 102. By means of the reinforcement frame 601, on one hand, it serves to protect the lower surface of the silicon substrate 103, and on the other hand, it coordinates from the lower surface of the silicon substrate 103 with the heat dissipation cover 501 on the upper surface and the lateral side of the silicon substrate 103, and it further adjusts and controls warping of the wafer-scale system in package structure, on yet another hand, the carving holes 603 provide limiting slots for the next level package and assembly to improve the accuracy of the mounting and alignment of the next level package and assembly.

The reinforcement frame 601 includes an intermediate frame and an edge frame located around the intermediate frame, the edge frame being connected with the intermediate frame, the edge frame being the edge area of the reinforcement frame 601, the intermediate frame being in the form of a “grid shape” with a plurality of carving holes 603, after the reinforcement frame 601 is mounted on the lower surface of the silicon substrate 103, each carving hole 603 correspondingly exposes a portion of the lower surface of the silicon substrate 103 directly underneath the corresponding functional sub-module 20. The edge frame of the reinforcement frame 601 is mounted together, on the one hand, with a portion of the lower surface of the edge area of the silicon substrate 103 and on the other hand, with the lower surface of the bottom end of the cover rim of the heat dissipation cover 501 on the outer side surface of the silicon substrate 103, and the intermediate frame of the reinforcement frame 601 is mounted together with a portion of the lower surface of the intermediate area of the silicon substrate 103.

The material of the reinforcement frame 601 is metal. The reinforcement frame 601 is mounted together with a portion of the lower surface of the silicon substrate 103 and the lower surface of the bottom end of the cover rim of the heat dissipation cover 501 on the outer side surface of the silicon substrate 103 by means of a bonding adhesive 604.

In one embodiment, the upper surface of the edge area of the reinforcement frame 601 has a protrusion structure 602, the lower surface of the bottom end of the cover rim of the heat dissipation cover 501 of the outer side surface of the silicon substrate 103 has a groove structure 505, and when the upper surface of the edge area of the reinforcement frame 601 is mounted together with the lower surface of the bottom end of the cover rim of the heat dissipation cover 501 of the outer side surface of the silicon substrate 103, the protrusion structure 602 of the upper surface of the edge area of the reinforcement frame 601 is mounted in a corresponding groove structure 505 of the lower surface of the bottom end of the cover rim of the heat dissipation cover 501 of the outer side surface of the silicon substrate 103 by means of a bonding adhesive 604. The groove structure 505 of the lower surface of the bottom end of the cover rim of the outer side of the heat dissipation cover 501 of the silicon substrate 103 serves as an anchor and alignment for mounting the reinforcement frame 601, and when the protrusion structure 602 on the edge area of the reinforcement frame 601 is accordingly mounted in the groove structure 505 of the lower surface of the bottom end of the cover rim of the heat dissipation cover 501, the protrusion structure 602 is limited in the groove structure 505, which can improve the firmness of mounting the reinforcement frame 601.

In another embodiment, the upper surface of the edge area of the reinforcement frame 601 has a groove structure, the lower surface of the bottom end of the cover rim of the heat dissipation cover 501 of the outer side of the silicon substrate 103 has a protrusion structure, and when the upper surface of the edge area of the reinforcement frame 601 is mounted together with the lower surface of the bottom end of the cover rim of the heat dissipation cover 501 of the outer side of the silicon substrate 103, the protrusion structure of the lower surface of the bottom end of the cover rim of the heat dissipation cover 501 of the outer side of the silicon substrate 103 is mounted in the corresponding groove structure of the upper surface of the edge area of the reinforcement frame 601 by means of a bonding adhesive. The protrusion structure of the lower surface of the bottom end of the cover rim of the heat dissipation cover 501 on the outer side of the silicon substrate 103 serves as an anchor and alignment for mounting the reinforcement frame 601, and when the protrusion structure of the lower surface of the bottom end of the cover rim of the heat dissipation cover 501 on the outer side of the silicon substrate 103 is correspondingly mounted in the groove structure of the upper surface of the edge area of the reinforcement frame 601, the protrusion structure is locked in the groove structure, which can improve the firmness of the mounting of the reinforcement frame 601.

Another embodiment of the present disclosure also provides a method for forming a wafer-scale system in package structure, and the forming method is described below in conjunction with the accompanying drawings (it should be noted that the parts of the present embodiment (the method for forming a wafer-scale system in package structure) which are the same or similar to those of the aforementioned embodiments (the wafer-scale system in package structure) will not be repeated in the present embodiment, and please refer to the corresponding parts of limitations or descriptions of the aforementioned embodiments for details).

Referring to FIG. 9, a silicon substrate 103 is provided, the silicon substrate 103 including opposed upper surface and lower surface.

The silicon substrate 103 includes a silicon wafer body 100, a first redistribution layer 101 located on the upper surface of the silicon wafer body 100 and a second redistribution layer 102 located on the lower surface of the silicon wafer body 100.

In one embodiment, the silicon substrate 103 includes an intermediate area 11 and an edge area 12 surrounding the intermediate area 11, and subsequently, a plurality of functional sub-modules 20, warping and stress adjustment structures 401, and stress cushioning flexible member structures 402 are all mounted on the upper surface of the intermediate area of the silicon substrate 103.

Referring to FIG. 10 and FIG. 11, a plurality of functional sub-modules 20 arranged in an array are mounted on the upper surface of the silicon substrate 103, the plurality of functional sub-modules 20 being electrically connected with the silicon substrate 103, and each of the functional sub-modules 20 including four corner heads and edges located between adjacent corner heads.

In one embodiment, before mounting the functional sub-module 20, a protective layer 110 is formed on the lower surface of the silicon substrate 103, the protective layer 110 being used in a subsequent process to protect the second redistribution layer 102 on the lower surface of the silicon substrate 103. The material of the protective layer 110 may be a metal (e.g., Al, Ti, TiW) or an inorganic material (e.g., silicon oxide or silicon nitride, etc.). After forming the protective layer 110, a temporary carrier board 113 is bonded on the lower surface of the protective layer 110 by means of a bonding layer 112, and the temporary carrier board 113 may be removed after subsequent relevant process steps have been completed.

In one embodiment, it further includes: mounting a plurality of edge dummy devices 301 on an upper surface of an edge area of the silicon substrate 103. The edge dummy devices 301 are one or more of a passive device, a heat dissipation discrete device, or a dummy piece. In one embodiment, an underfill layer 302 may be covered between the edge dummy devices 301 close to the intermediate area 11 and the upper surface of the silicon substrate 103, as well as on the sidewalls of the edge dummy devices.

In one embodiment, each of the sub-modules 20 includes at least two semiconductor chips 201, the semiconductor chips 201 being mounted on the upper surface of the silicon substrate 103 by means of flip-flop manner. Each of the functional sub-modules 20 further includes an underfill layer 205 filled between the semiconductor chips 201 of the functional sub-modules 20 and the upper surface of the silicon substrate 103 and covering the sides of the semiconductor chips 201.

With continuing reference to FIG. 10, a warping and stress adjustment structure 401 is mounted on the upper surface of the silicon substrate 103 at the edges of the functional sub-module 20; and a stress cushioning flexible member structure 402 is mounted on the upper surface of the silicon substrate 103 at the corner heads of the functional sub-module 20 (referring to FIG. 2 or FIG. 3).

In one embodiment, the warping and stress adjustment structure 401 includes a flexible layer 404 and a rigid layer 403 located on the upper surface of the flexible layer 404, the rigidity of the flexible layer 404 being smaller than the rigidity of the rigid layer 403.

In one embodiment, mounting the warping and stress adjustment structure 401 on the upper surface of the silicon substrate 103 includes: mounting the warping and stress adjustment structure 401 directly on the upper surface of the silicon substrate 103 by means of a bonding adhesive, or floatingly mounting the warping and stress adjustment structure 401 by means of a bonding adhesive (as shown in FIG. 11) on the inclined sidewalls side of the underfill layer 205 of side of an adjacent functional sub-module 20.

In another embodiment, the warping and stress adjustment structure 401 is one or more of a flip chip, a surface mount device, a functional device, a structural dummy piece, or a heat dissipation dummy piece (referring to FIG. 4).

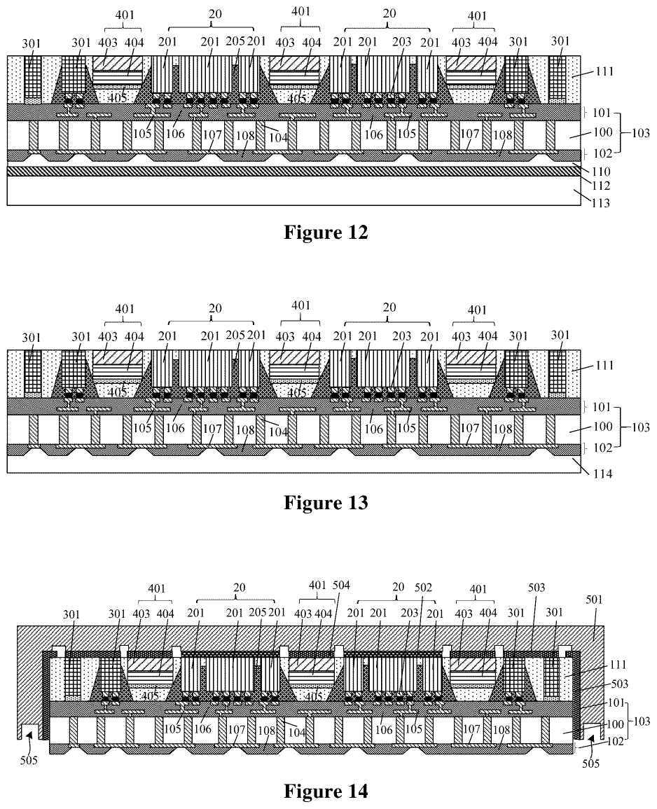

In one embodiment, the stress cushioning flexible member structure 402 includes a first cushioning layer 406, a core layer 408 located on the upper surface of the first cushioning layer 406, and a second cushioning layer 407 located on the upper surface of the core layer 408, the second cushioning layer 407 and the core layer 408 having in them a blind hole 409, the opening of the blind hole 409 being closed by a portion of the second cushioning layer 407, and in subsequent formation of the molding layer 111 (referring to FIG. 12), when thinning the molding layer, a portion of the second cushioning layer 407 is removed in order to expose the blind holes 409, and in subsequent mounting of the heat dissipation cover 501, the anchoring protrusions 506 on the lower surface of the heat dissipation cover 501 are mounted in the corresponding blind holes 409 by means of a bonding adhesive (referring to FIG. 15).

In another embodiment, the stress cushioning flexible member structure 402 includes a first cushioning layer 406, a core layer 408 located on the upper surface of the first cushioning layer 406, and a second cushioning layer 407 located on the upper surface of the core layer 408, and the core layer 408 has in it a blind hole 409, the blind hole 409 has in it a cavity or is fully filled with a filler material 411 (referring to FIG. 5), and subsequently, when carrying out the mounting of the heat dissipation cover 501, a portion of the lower surface of the heat dissipation cover 501 is mounted on the surface of the second cushioning layer 407 by means of a bonding adhesive.

Referring to FIG. 12, a molding layer 111 is formed on the upper surface of the silicon substrate 103, covering the functional sub-module 20, the warping and stress adjustment structure 401, the stress cushioning flexible member structure 402, and the edge dummy device 301, the molding layer 111 exposing the upper surface of the functional sub-module 20, the warping and stress adjustment structure 401, the stress cushioning flexible member structure 402, and the edge dummy device 301.

In one embodiment, before forming the molding layer 111, it further includes: forming, in the silicon substrate 103 of the edge area 12, a trench 109 (referring to FIG. 6 and FIG. 7) running through or not running through the silicon substrate 103; and when forming the molding layer 111, the molding layer 111 further fully fills the trench 109. Before mounting the heat dissipation cover, the edge area is cut and removed along the trench 109 to form a wafer-scale system in package structure (referring to FIG. 8).

In one embodiment, before mounting the heat dissipation cover 501, referring to FIG. 13 and FIG. 14, the carrier board 113 is removed to form a flexible detachable protective film 114 on the lower surface of the silicon substrate 103, and the detachable protective film 114 is removed after the subsequent mounting of the heat dissipation cover 501. The detachable protective film 114 provides a flat mounting plane for the subsequent mounting of the heat dissipation cover 501, and this mounting plane needs to be adsorbed directly onto the vacuum platform of the mounting device. Since the mounting process of the heat dissipation cover 501 needs to undergo a hot press of about 150° C. to ensure that the hot press mounting of the heat dissipation cover 501 is performed in the case that the wafer-scale system in package structure is in a small warping condition, thus the detachable protective film 114 needs to be flexible and be able to withstand a hot press fit process of about 150° C. and 10 minutes.

In one embodiment, referring to FIG. 14 and FIG. 15, it further includes: mounting a heat dissipation cover 501 on the upper surface of the molding layer 111, the functional sub-module 20, the warping and stress adjustment structure 401 and the stress cushioning flexible member structure 402, as well as on the outer side of the molding layer 111 and the silicon substrate 103.

In one embodiment, the heat dissipation cover 501 includes a horizontal cover top and a cover rim protruding from the lower surface of an edge of the horizontal cover top, the lower surface of the horizontal cover top of the heat dissipation cover 501 being mounted on the upper surfaces of the molding layer 111, the functional sub-module 20, the warping and stress adjustment structure 401, and the stress cushioning flexure member structure 402, and the inner wall surface of the cover rim of the heat dissipation cover 501 being mounted on the outer side surfaces of the molding layer 111 and the silicon substrate 103.

In one embodiment, the lower surface of the horizontal cover top of the heat dissipation cover 501 has a plurality of downwardly protruding anchoring protrusions 506, the anchoring protrusions 506 being mounted in corresponding blind holes 409 by means of bonding adhesive 503.

In one embodiment, referring to FIG. 16 and FIG. 17, it further includes: mounting a reinforcement frame 601 on the lower surface of the silicon substrate 103, and the upper surface of the edge area of the reinforcement frame 601 is mounted together with the lower surface of the bottom end of the cover rim of the heat dissipation cover 501 on the outer side of the silicon substrate 103. The reinforcement frame 601 has in it a plurality of carving holes 603, the carving holes 603 exposing a portion of the second redistribution layer 102 when the reinforcement frame 601 is mounted.

In one embodiment, the upper surface of the edge area of the reinforcement frame 601 has a protrusion structure 602, and the lower surface of the bottom end of the cover rim of the heat dissipation cover 501 on the outer side of the silicon substrate 103 has a groove structure 505, and when the upper surface of the edge area of the reinforcement frame 601 is mounted together with the lower surface of the bottom end of the cover rim of the heat dissipation cover 501 on the outer side of the silicon substrate 103, the protrusion structure 602 of the upper surface of the edge area of the reinforcement frame 601 is mounted in the corresponding groove structure 505 in the lower surface of the bottom end of the cover rim of the heat dissipation cover 501 of the outer side of the silicon substrate 103 by means of a bonding adhesive 604.

In another embodiment, the upper surface of the edge area of the reinforcement frame 601 has a groove structure, and the lower surface of the bottom end of the cover rim of the heat dissipation cover 501 of the outer side of the silicon substrate 103 has a protrusion structure, and when the upper surface of the edge area of the reinforcement frame 601 is mounted together with the lower surface of the bottom end of the cover rim of the heat dissipation cover 501 of the outer side of the silicon substrate 103, the protrusion structure of the bottom lower surface of the cover rim of the heat dissipation cover 501 of the outer side of the silicon substrate 103 is mounted in the corresponding groove structure of the upper surface of the edge area of the reinforcement frame 601 by means of a bonding adhesive.

Although the present disclosure has been disclosed as above with certain embodiments, it is not intended to limit the present disclosure, and any skilled in the art may, without departing from the spirit and scope of the present disclosure, make possible changes and modifications to the technical solutions of the present disclosure by utilizing the above disclosed methods and technical contents, therefore, any simple modifications, equivalent changes, and modifications made to the above embodiments based on the technical substance of the present disclosure without departing from the content of the technical solutions of the present disclosure are within the scope of protection of the technical solutions of the present disclosure.

What is claimed is:

1. A wafer-scale system in package structure, comprising:
a silicon substrate, the silicon substrate comprising opposed upper surface and lower surface;
a plurality of functional sub-modules arranged in an array mounted on the upper surface of the silicon substrate, the plurality of functional sub-modules being electrically connected with the silicon substrate, and each of the functional sub-modules comprising four corner heads and edges located between adjacent corner heads;
a warping and stress adjustment structure mounted on the upper surface of the silicon substrate at the edges of the functional sub-modules;
a stress cushioning flexible member structure mounted on the upper surface of the silicon substrate at the corner heads of the functional sub-module;
edge dummy devices of different sizes mounted on the upper surface of an edge area of the silicon substrate outside the array of the functional sub-modules; and
a molding layer located on the upper surface of the silicon substrate, the molding layer covering the functional sub-modules, the warping and stress adjustment structure, the stress cushioning flexible member structure, and edge dummy devices, the molding layer exposing the upper surface of the functional sub-modules, the warping and stress adjustment structure, the stress cushioning flexible member structure, and edge dummy devices.

2. The wafer-scale system in package structure according to claim 1, wherein the warping and stress adjustment structure comprises a flexible layer and a rigid layer located on the upper surface of the flexible layer, and a rigidity of the flexible layer is smaller than a rigidity of the rigid layer.

3. The wafer-scale system in package structure according to claim 2, wherein a material of the rigid layer of the warping and stress adjustment structure is silicon, silicon germanium or silicon carbide, and a material of the flexible layer is at least one of a filler and a fiber-filled polymer composite material.

4. The wafer-scale system in package structure according to claim 2, wherein the warping and stress adjustment structure is mounted on the upper surface of the silicon substrate, comprising:
the warping and stress adjustment structure being directly contact-mounted on the upper surface of the silicon substrate, or the warping and stress adjustment structure being floatingly mounted on the upper surface of the silicon substrate.

5. The wafer-scale system in package structure according to claim 1, wherein the warping and stress adjustment structure is one or more of a flip chip, a surface mount device, a functional device, a structural dummy piece, or a heat dissipation dummy piece.

6. The wafer-scale system in package structure according to claim 2, whereinthe number of warping and stress adjustment structures mounted on the upper surface of the silicon substrate at each edge of the functional sub-module is at least two, and the plurality of the warping and stress adjustment structures are arranged along a direction parallel to the edge of the functional sub-module.

7. The wafer-scale system in package structure according to claim 1, wherein
the silicon substrate comprises an intermediate area and an edge area surrounding the intermediate area;
a plurality of functional sub-modules are mounted on the upper surface of the intermediate area of the silicon substrate; and
a plurality of dummy devices are mounted on the upper surface of the edge area of the silicon substrate.

8. The wafer-scale system in package structure according to claim 7, wherein the dummy devices are one or more of a passive device, a heat dissipation discrete member, or a dummy piece.

9. The wafer-scale system in package structure according to claim 7, wherein a dimension of the dummy devices far away from the intermediate area is smaller than a dimension of the dummy devices close to the intermediate area.

10. The wafer-scale system in package structure according to claim 7, wherein the silicon substrate in the edge area further has a trench, the trench running through or not running through the silicon substrate, and the molding layer further fully fills the trench.

11. The wafer-scale system in package structure according to claim 1, further comprising:
a heat dissipation cover mounted on the upper surface of the molding layer, the functional sub-module, the warping and stress adjustment structure, and the stress cushioning flexible member structure, as well as on an outer side of the molding layer and the silicon substrate,
wherein the heat dissipation cover comprises a horizontal cover top and a cover rim protruding from the lower surface of an edge of the horizontal cover top;
the lower surface of the horizontal cover top is horizontal or has an optional downward protrusion in a corresponding area of the functional sub-module, the warping and stress adjustment structure, and the stress cushioning flexible member structure;
the lower surface of the horizontal cover top of the heat dissipation cover is mounted on the upper surface of the molding layer, the functional sub-module, the warping and stress adjustment structure, and the stress cushioning flexible member structure; and
a surface of an inner wall of the cover rim of the heat dissipation cover is mounted on an outer side surface of the molding layer and of the silicone substrate.

12. The wafer-scale system in package structure according to claim 11, wherein the stress cushioning flexible member structure is a flexible structure, and a rigidity of the stress cushioning flexible member structure is smaller than a rigidity of the molding layer.

13. The wafer-scale system in package structure according to claim 11, wherein the stress cushioning flexible member structure comprises a first cushioning layer, a core layer located on the upper surface of the first cushioning layer, and a second cushioning layer located on the upper surface of the core layer, the second cushioning layer and the core layer having in them blind holes running through the second cushioning layer and the core layer, the molding layer exposing the blind holes.

14. The wafer-scale system in package structure according to claim 13, wherein the lower surface of the horizontal cover top of the heat dissipation cover has a plurality of downward protruding anchoring protrusions, the anchoring protrusions being mounted in corresponding blind holes by a bonding adhesive.

15. The wafer-scale system in package structure according to claim 11, wherein the stress cushioning flexible member structure comprises a first cushioning layer, a core layer located on the upper surface of the first cushioning layer, and a second cushioning layer located on the upper surface of the core layer, the core layer having in it blind holes, and a portion of the lower surface of the horizontal cover top of the heat dissipation cover being mounted on the upper surface of the second cushioning layer by a bonding adhesive.

16. The wafer-scale system in package structure according to claim 11, further comprising:
a reinforcement frame mounted on the lower surface of the silicon substrate,
wherein the upper surface of an edge area of the reinforcement frame is mounted together with the lower surface of a bottom end of the cover rim of the heat dissipation cover on an outer side of the silicon substrate.

17. The wafer-scale system in package structure according to claim 16, wherein
the upper surface of an edge area of the reinforcement frame has a groove structure;
the lower surface of a bottom end of the cover rim of the heat dissipation cover of an outer side of the silicon substrate has a protrusion structure; and
when the upper surface of the edge area of the reinforcement frame is mounted together with the lower surface of the bottom end of the cover rim of the heat dissipation cover of the outer side of the silicon substrate, the protrusion structure on the lower surface of the bottom end of the cover rim of the heat dissipation cover of the outer side of the silicon substrate is mounted in a corresponding groove structure of the upper surface of the edge area of the reinforcement frame by a bonding adhesive.

18. The wafer-scale system in package structure according to claim 1, wherein
the structure of each functional sub-module is the same;
the functional sub-modules comprises at least two semiconductor chips;
the at least two semiconductor chips are mounted on the upper surface of the silicon substrate in a flip-flop manner; and
each functional sub-module further comprises an underfill layer filled between the lower surface of the semiconductor chip in each functional sub-module and the upper surface of the silicon substrate and covering sides of the semiconductor chip.

19. The wafer-scale system in package structure according to claim 1, wherein a diagonal dimension of the silicon substrate is 300 or 450±10 mm, or a diameter of the silicon substrate is 300 mm or 450±5 mm.

20. A method for forming a wafer-scale system in package structure, comprising:
providing a silicon substrate, the silicon substrate comprising opposed upper surface and lower surface;
mounting a plurality of functional sub-modules arranged in an array on the upper surface of the silicon substrate, the plurality of functional sub-modules being electrically connected with the silicon substrate, and each of the functional sub-modules comprising four corner heads and edges located between adjacent corner heads;
mounting a warping and stress adjustment structure on the upper surface of the silicon substrate at the edges of the functional sub-modules;
mounting a stress cushioning flexible member structure on the upper surface of the silicon substrate at the corner heads of the functional sub-module;
mounting edge dummy devices of different sizes on the upper surface of an edge area of the silicon substrate outside the array of the functional sub-modules; and
forming a molding layer on the upper surface of the silicon substrate, the molding layer covering the functional sub-modules, the warping and stress adjustment structure, the stress cushioning flexible member structure, and edge dummy devices, the molding layer exposing the upper surface of the functional sub-modules, the warping and stress adjustment structure, the stress cushioning flexible member structure, and edge dummy devices.
